(19) United States
(12) Patent Application Publication
(10) Pub. No.: US 2024/0371666 A1
(43) Pub. Date: Nov. 7, 2024

(54) IN-LINE WAFER EDGE SEALING MONITORING SYSTEM AND METHODS OF OPERATION

(71) Applicant: Taiwan Semiconductor Manufacturing Company, Ltd., Hsinchu (TW)

(72) Inventors: Hau-Yi HSIAO, Chiayi City (TW); Kuo-Ming WU, Tainan City (TW); Sheng-Chau CHEN, Tainan City (TW); Ru-Liang LEE, Hsinchu (TW)

(21) Appl. No.: 18/348,546

(22) Filed: Jul. 7, 2023

Related U.S. Application Data
(60) Provisional application No. 63/500,442, filed on May 5, 2023.

(51) Int. Cl. H01L 21/67; G01B 11/24; H01L 21/56; H01L 21/66

(52) U.S. Cl. CPC H01L 21/67253; G01B 11/2441; H01L 21/56; H01L 21/67126; H01L 22/26

(57) ABSTRACT

Some implementations herein provide for a system and methods for in-line monitoring of a sealant being dispensed by a jet nozzle in a beveled region along a perimeter of a stack of semiconductor substrates. The system includes an automated optical inspection system. During the dispensing of the sealant by the jet nozzle, the automated optical inspection system may monitor an amount of an accumulation of the sealant within the beveled region.

### CROSS-REFERENCE TO RELATED APPLICATION

This patent application claims priority to Provisional Patent Application No. 63/500,422 filed on May 5, 2023, and entitled “In-Line Wafer Edge Sealing Monitoring System and Methods of Operation.” The disclosure of the prior Application is considered part of and is incorporated by reference into this patent application.

### BACKGROUND

A three dimensional integrated circuit (3DIC) assembly may include two or more integrated circuit (IC) dies that are stacked vertically and bonded along a bond line. The 3DIC assembly may be formed by stacking two or more semiconductor substrates including the two or more IC dies using a wafer bonding operation such as a Wafer-on-Wafer (WoW) bonding operation. After the bonding operation, the 3DIC assembly including the two or more IC dies may be diced from the stack of two or more semiconductor substrates and encapsulated in a semiconductor die package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor sealant tool described herein.

FIG. 2 is a diagram of an example implementation of formation of a stacked die product described herein.

FIG. 3 is a diagram of an example implementation of a sealant described herein.

FIG. 4 is a diagram of an example sealant dispensing system described herein.

FIGS. 5A-5D are diagrams of an example series of operations using the semiconductor sealant tool described herein.

FIG. 6 is a diagram of an example semiconductor substrate grinding tool described herein.

FIG. 7 is a diagram of example components of one or more devices of FIGS. 1, 4, and 6 described herein.

FIGS. 8 and 9 are flowcharts of example process associated with an in-line wafer edge sealing monitor descried herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a partially completed stack of semiconductor substrates (e.g., a WoW assembly) used to form a stacked integrated circuit die product may include a beveled region (e.g., a lateral gap region near a perimeter of the stack semiconductor substrates). The beveled region may be between edges of the stack of semiconductor substrates and along a perimeter region of the stack of semiconductor substrates. In some cases, the beveled region may be filled with a sealant to improve a robustness (e.g., absorb vibrations) of the stack of semiconductor substrates during manufacturing and reduce a likelihood of damage during a manufacturing process (e.g., peeling at a bonding interface within the stack of semiconductor substrates).

Techniques for forming the sealant within the beveled region may include using a jet nozzle to dispense the sealant around the perimeter of the stack of semiconductor substrates. An amount of the sealant dispensed within the beveled region is critical to maintaining a quality of the stack of semiconductor substrates during manufacturing. For example, if the amount of the sealant is too little and/or if a profile of the sealant fails to extend to a lower boundary threshold, a risk of peeling at the bonding interface within the stack of semiconductor substrates may increase. Alternatively, if the amount of the sealant is too much and/or a profile of the sealant extends beyond an upper boundary threshold, a risk of the sealant flowing out of the beveled region may increase to cause contamination issues to integrated circuitry included in the stack of semiconductor substrates.

Current techniques to control the amount of sealant include off-line collection and evaluation of scanning electron microscope (SEM) data and/or atomic force microscopy (AFM) data to determine amounts of the sealant to be dispensed and locations along the perimeter region of the stack of semiconductor substrates to dispense the sealant. However, the techniques fail to provide a monitor that contemporaneously verifies that the amount of sealant dispensed by the jet nozzle satisfies a volume threshold and/or that a profile of the sealant satisfies upper and lower boundary thresholds.

Some implementations herein provide for a system and methods for in-line monitoring of a sealant being dispensed by a jet nozzle in a beveled region along a perimeter of a stack of semiconductor substrates. The system includes an automated optical inspection system. During the dispensing of the sealant by the jet nozzle, the automated optical inspection system may monitor an amount of an accumulation of the sealant within the beveled region.

Through in-line monitoring during a dispense operation that dispenses the sealant into the beveled region, a consistency of amounts and/or profiles of the sealant across a population of stacks of semiconductor substrates may be improved. Through this improvement, a yield of the population of stacks of semiconductor substrates may increase relative to another population of stacks of semiconductor substrates where detecting amounts and/or profiles of the sealant rely on off-line monitoring using SEM data and/or AFM data techniques. In this way, an amount of resources (e.g., semiconductor manufacturing tools, raw materials, labor, and/or computing resources) needed to manufacture the population of the stacks of semiconductor substrates is reduced.

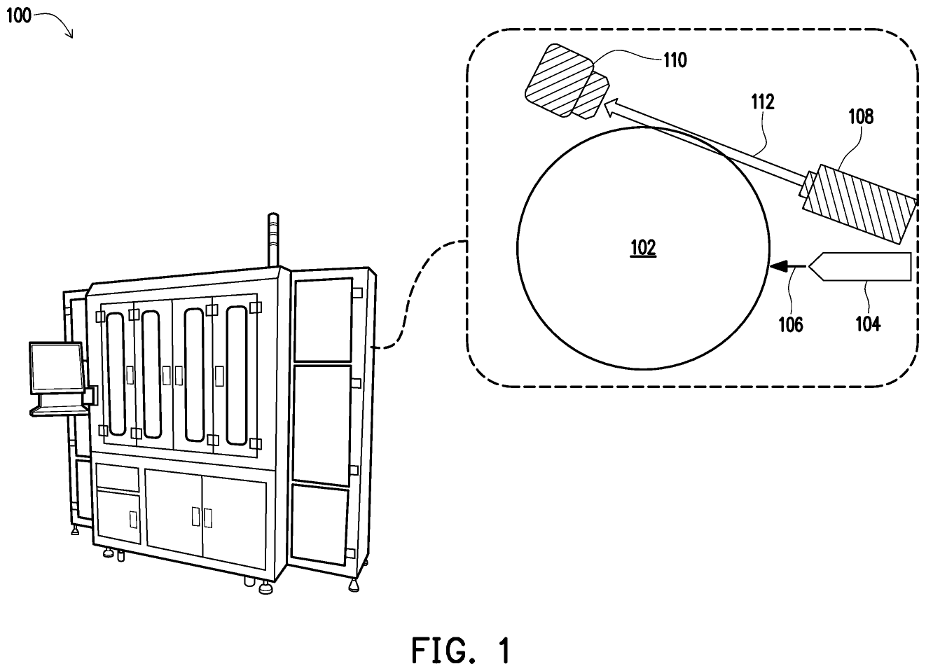

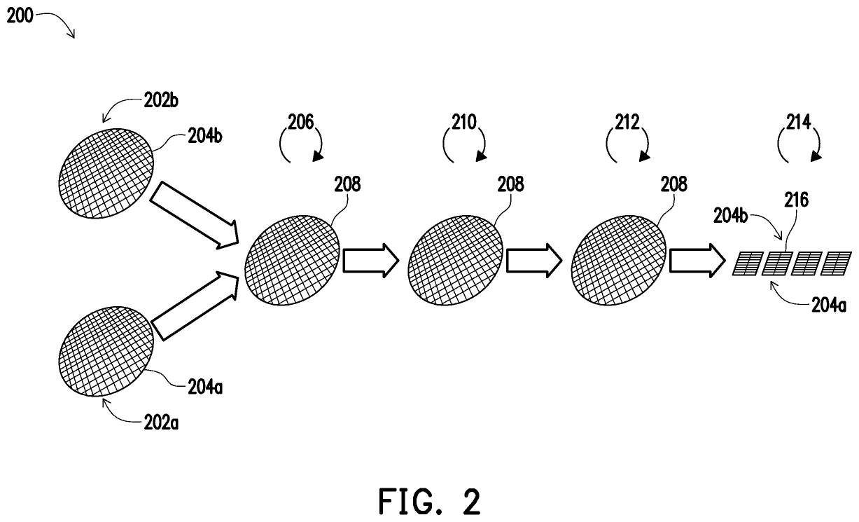

FIG. 1 is a diagram of an example semiconductor sealant tool 100 described herein. As described in greater detail in connection with FIGS. 2-9, the semiconductor sealant tool 100 may perform operations related to dispensing a sealant into a beveled region that is between a pair of semiconductor substrates (e.g., silicon wafers) that are bonded together and along a perimeter of the pair of semiconductor substrates.

The semiconductor sealant tool 100 includes a platen 102 that may hold and/or rotate a stack of semiconductor substrates. In some implementations, the platen 102 includes a chucking component such as an electrostatic chuck (ESC) or a vacuum chuck to secure the stack of semiconductor substrates to the platen 102. In some implementations, the platen 102 includes a motor component to rotate the platen 102. A rotational velocity of the platen 102 (e.g., the motor component) may be adjustable.

The semiconductor sealant tool 100 further includes a jet nozzle 104 that is used to dispense a sealant 106 into the beveled region between the stack of semiconductor substrates. In some implementations, the jet nozzle 104 includes a pump system having an adjustable pressure and/or dispense rate. Furthermore, and in some implementations, the jet nozzle 104 is linked with a positioning system that can be used to adjust an aim point of the jet nozzle 104. The jet nozzle 104 may dispense the sealant 106 along an axis that is approximately orthogonal to another axis about which the platen 102 rotates the stack of semiconductors.

The semiconductor sealant tool 100 further includes an automated optical inspection system that includes a light source 108 and an optical sensor 110. The light source 108 may include a combination of one or more components. For example, the light source 108 may include one or more light emitting diode components configured to emit electromagnetic waves corresponding to, among other examples. Additionally, or alternatively, the light source 108 may include a lens component, a mirror component, and/or a beam splitting component.

The optical sensor 110 may include a combination of one or more components configured to detect electromagnetic waves. For example, the optical sensor 110 may include one or more photodiode components or a camera component configured to detect a white light, a red light, a green light, or another color of light, among other examples. Additionally, or alternatively, the optical sensor may include a lens component and/or a mirror component.

The light source 108 may project electromagnetic waves 112 (e.g., light waves) towards the beveled region of the pair of semiconductor substrates being rotated by the platen 102. Using electromagnetic waves reflected from the beveled region, the optical sensor 110 may collect and provide optical feedback that may be used to monitor, in real time, an accumulation of the sealant 116 within the beveled region during a sealing operation being performed by the semiconductor sealant tool 100.

As an example, the automated optical inspection system may use interferometry techniques as part of an in-line monitoring operation. In such a case, the light source 108 may project and split a white light into a first set of light waves along a target path that leads to the beveled region and into a second set of light waves along an adjacent reference path. The automated inspection system may recombine portions of the first set of light waves that are reflected from the beveled region (and as collected by the optical sensor 110) with the second set of light waves (as collected by the optical sensor 110) to determine an interference pattern. The automated optical inspection system may analyze the interference pattern to monitor an accumulation (e.g., an amount or a profile) of the sealant 116 within the beveled region.

As another example, the automated optical inspection system may use three-dimensional laser triangulation techniques as part of an in-line monitoring process. In such a case, the light source 108 projects a laser light towards the beveled region. The automated inspection system may analyze positions of one or more portions of the laser light that are reflected from the beveled region (and as collected by the optical sensor 110) to monitor an accumulation (e.g., an amount or a profile) of the sealant 116 within the beveled region.

In some implementations, the semiconductor sealant tool 100 performs a series of operations. As described in greater detail in connection with FIGS. 2-9, and elsewhere herein, the series of operations includes receiving, in the semiconductor sealant tool 100, a stack of bonded semiconductor substrates including a pair of bonded semiconductor substrates. The series of operations includes performing, using the semiconductor sealant tool 100, a sealing operation that includes dispensing the sealant 106 into a beveled region between the pair of semiconductor substrates along a perimeter of the pair of bonded semiconductor substrates, where optical feedback that is related to an accumulation of the sealant 106 within the beveled region is obtained during the sealing operation, and where a dispense rate of the sealant 106 is adjusted during the sealing operation based on whether the accumulation of the sealant within the beveled region satisfies a threshold.

The number and arrangement of components shown in FIG. 1 are provided as one or more examples. In practice, there may be additional components, fewer components, different components, or differently arranged components than those shown in FIG. 1. Furthermore, two or more components shown in FIG. 1 may be implemented within a single system, or a single component shown in FIG. 1 may be implemented as multiple, distributed systems. Additionally, or alternatively, a set of components (e.g., one or more components) of the FIG. 1 may perform one or more functions described as being performed by another set of components.

FIG. 2 is a diagram of an example implementation 200 of formation of a stacked die product described herein. The implementation 200 may correspond to a “Wafer-on-Wafer” (WoW) technique used to form a three-dimensional integrated circuit die (3DIC) product, among other examples. The example implementation 200 may use one or more semiconductor processing tools including to form the stacked die product.

As shown, a semiconductor substrate 202a may include an integrated circuit die 204a and a semiconductor substrate 202b may include an integrated circuit die 204b. The integrated circuit dies 204a and 204b may be formed using a series of deposition operations by a deposition tool, a series of patterning operations by an exposure tool, and a series of etch operations by an etch tool, among other examples.

A bonding operation (e.g., a bonding operation by a semiconductor substrate bonding/debonding tool, among other examples) may align the integrated circuit dies 204a and 204b and bond the semiconductor substrate 202a and the semiconductor substrate 202b to form a stack of semiconductor substrates 208. As a result of the bonding operation 206, integrated circuitry of the integrated circuit dies 204a and 204b may be electrically connected for signaling purposes (e.g., inputs/output signaling, clocking or timing signaling, and/or power signaling, among other examples). The bonding operation 206 may include a eutectic bonding operation, a hybrid bonding operation, and/or another type of bonding operation.

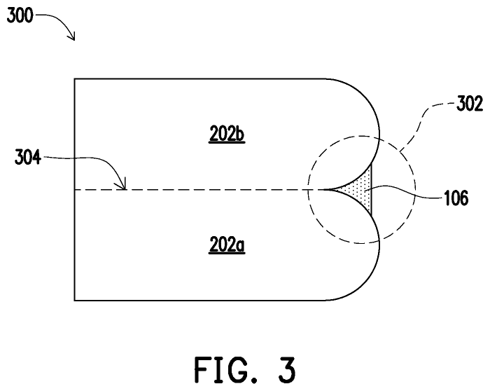

To conserve space in a final semiconductor die package, a thinning operation 210 (e.g., a thinning operation by a planarization tool may be performed to a top substrate of the stack of semiconductor substrates 208 (e.g., the semiconductor substrate 202a including the integrated circuit die 204a). In some implementations, and as described in greater detail in connection with FIGS. 3-9 and elsewhere herein, a sealant may be dispensed in beveled regions between the semiconductor substrate 202a and the semiconductor substrate 202b. The sealant may improve a robustness of the stack of semiconductor substrates 208 during the thinning operation 210 and/or subsequent operations performed to the stack of semiconductor substrates 208. For example, and by improving the robustness of the stack of semiconductor substrates, a likelihood of defects and/or yield loss within the stack of semiconductor substrates 208 due to trim-loss, trim wall exposure, and/or trim peeling that is inherent to a trimming operation may be reduced. Additionally, or alternatively and in some implementations, such a trimming operation is eliminated.

A bumping operation 212 (e.g., a bumping operation by a bumping tool, among other examples) may form connection structures (e.g., solder balls, among other examples) on pads of integrated circuit dies of a top semiconductor substrate (e.g., the integrated circuit die 204a of the semiconductor substrate 202a). Such connection structures may be used for a testing operation and/or a packaging operation that encapsulates a stacked die product from the stack of semiconductor substrates 208.

A downstream series of operations 214 may include a testing operation and a dicing operation to test a stacked die product 216 (e.g., the integrated circuit die 204a joined to the integrated circuit die 204b) and extract the stacked die product 216 from the stack of semiconductor substrates. The testing operation (e.g., a testing operation by an automated test equipment (ATE) test tool, among other examples) may ensure a quality of the bonding operation 210 and/or a quality of the integrated circuit dies included in the stack of semiconductor substrates 208 (e.g., the integrated circuit die 202a and/or the integrated circuit die 204b, among other examples). The testing operation may include a functionality test, a parametric test, and/or a reliability test, among other examples. The dicing operation to extract the stacked die product 216 from the stack of semiconductor substrates 208 may be performed by a singulation tool or sawing tool, among other examples.

As indicated above, FIG. 2 is provided as an example. Other examples may differ from what is described with regard to FIG. 2.

FIG. 3 is a diagram of an example implementation 300 of a sealant described herein. In some implementations, the sealant corresponds to the sealant 116 of FIG. 1. As shown in FIG. 3, the sealant 116 occupies a beveled region 302 that is between the semiconductor substrate 202a and the semiconductor substrate 202b. The beveled region 302 may be along a perimeter of the semiconductor substrate 202a and the semiconductor substrate 202b and adjacent to a bond interface 304 between the semiconductor substrate 202a and the semiconductor substrate 202b (e.g., a bond interface formed during formation of stacked die product as described in connection with FIG. 2).

The sealant 116 may include a material such as a dimethyldiethoxysilane (DMDEOS) compound, a tetraethyl orthosilicate (TEOS) compound, a polydimethylsiloxane (PDMS) compound, or a polysilazanes (PHPS) compound. In some implementations, the sealant may include composite filler particulates such as silicon carbide (SiC) composite filler particulates, aluminum dioxide (Al₂O₃) composite filler particulates, zirconium tungsten phosphate (Zr₂WP₂O₁₂ or ZWP) composite filler particulates, silica (SiO₂) composite filler particulates, and/or ceramic composite particulates. Such composite filler particulates may improve a robustness of the sealant and reduce a likelihood of tearing within the sealant.

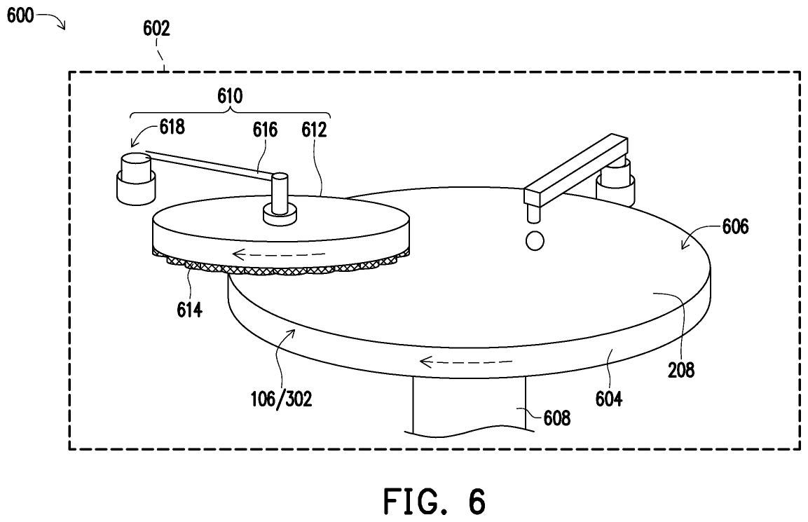

As described in greater detail in connection with FIG. 6, the sealant 116 may reduce a likelihood of damage to the semiconductor substrates 202a and/or 202b during a grinding or thinning operation. Through in-line monitoring during a dispense operation that dispenses the sealant 116 into the beveled region 302, a consistency of amounts and/or profiles of the sealant 116 across a population of stacks of semiconductor substrates may be improved. Through this improvement, a yield of the population of stacks of semiconductor substrates may increase relative to another population of stacks of semiconductor substrates where detecting amounts and/or profiles of the sealant 116 rely on off-line monitoring using SEM data and/or AFM data techniques.

As indicated above, FIG. 3 is provided as an example. Other examples may differ from what is described with regard to FIG. 3.

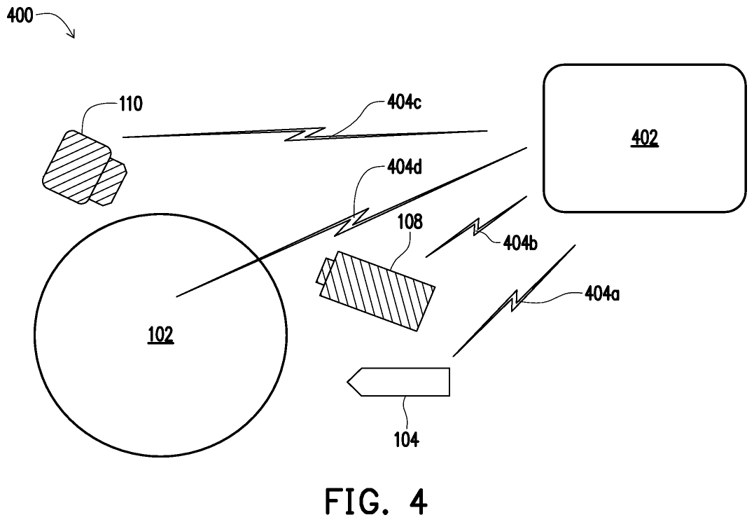

FIG. 4 is a diagram of an example sealant dispensing system 400 described herein. In some implementations, the sealant dispensing system 400 is included in the semiconductor sealant dispense tool 100 of FIG. 1. As shown in FIG. 4, the sealant dispensing system 400 includes the platen 102, the jet nozzle 104, the light source 108, and the optical sensor 110.

The sealant dispensing system 400 further includes a controller 402. The controller 402 (e.g., a processor, a combination of a processor and memory, among other examples) may communicate with the platen 102 (e.g., a motor component of the platen), the jet nozzle 104 (e.g., a pump component or a valve component of the jet nozzle 104), the light source 108, and/or the optical sensor 110 using one or more communication links 404a-404d. The one or more communication links 404a-404d may include or more wireless-communication links, one or more wired-communication links, or a combination of one or more wireless-communication links and one or more wired-communication links, among other examples. In some implementations, the controller 402 is separate from a tool including the platen 102, the jet nozzle 104, the light source 108, and/or the optical sensor 110 (e.g., separate from the semiconductor sealant tool 100).

In some implementations, and based on optical feedback received from the optical sensor 110, the controller 402 adjusts one or more settings related to a dispense rate of a sealant 116 from the jet nozzle 104 (e.g., the controller 402 may adjust a valve setting, an orifice setting, and/or a pump pressure setting). Additionally, or alternatively, the controller 402 may adjust one or more settings related to a rotational velocity of the platen 102 (e.g., the controller 402 may adjust a motor setting) based on optical feedback received from the optical sensor 110. Additionally, or alternatively, the controller 402 may adjust one or more settings related to an aim point of the jet nozzle 104 (e.g., the controller 402 may adjust a positioning system setting) based on optical feedback received from the optical sensor 110.

The controller 402 may make the adjustments related to the dispense rate of the sealant 116, the rotational velocity of the platen 102, and/or the aim point of the jet nozzle 104 using a machine learning model. The machine learning model may include and/or may be associated with one or more of a neural network model, a random forest model, a clustering model, or a regression model, among other examples. In some implementations, the controller 402 uses the machine learning model to adjust a setting by providing candidate settings as input to the machine learning model, and using the machine learning model to determine a likelihood, probability, or confidence that a particular outcome (e.g., an amount or profile of the sealant 116 within the beveled region 302) for a subsequent sealing operation will be achieved using the candidate parameters. In some implementations, the controller 402 provides an amount and/or profile of the sealant 116 within the beveled region 302 as input to the machine learning model, and the controller 402 uses the machine learning model to determine or identify a particular combination of parameters and/or settings related to the dispense rate of the sealant 116, the rotational velocity of the platen 102, and/or the aim point of the jet nozzle 104 that are likely to achieve the amount and/or profile of the sealant 116.

The controller 402 (or another system) may train, update, and/or refine the machine learning model to increase the accuracy of the outcomes and/or parameters determined using the machine learning model. The controller 402 may train, update, and/or refine the machine learning model based on feedback and/or results from the subsequent stacked semiconductor substrate sealing operations, as well as from historical or related stacked semiconductor substrate scaling operations (e.g., from hundreds, thousands, or more historical or related stacked semiconductor substrate sealing operations) performed using the sealant dispensing system 400 (and/or the semiconductor sealant tool 100).

In some implementations and under direction of the controller 402, the sealant dispensing system 400 performs a series of operations. The series of operations includes projecting electromagnetic waves (e.g., the electromagnetic waves 112) towards a beveled region (e.g., the beveled region 302) between a pair of bonded semiconductor substrates (e.g., the semiconductor substrate 202a and the semiconductor substrate 202b) being rotated. The series of operations includes analyzing reflected electromagnetic waves from the beveled region to determine an amount of a sealant (e.g., an amount of the sealant 116) within the beveled region.

As indicated above, FIG. 4 is provided as an example. Other examples may differ from what is described with regard to FIG. 4.

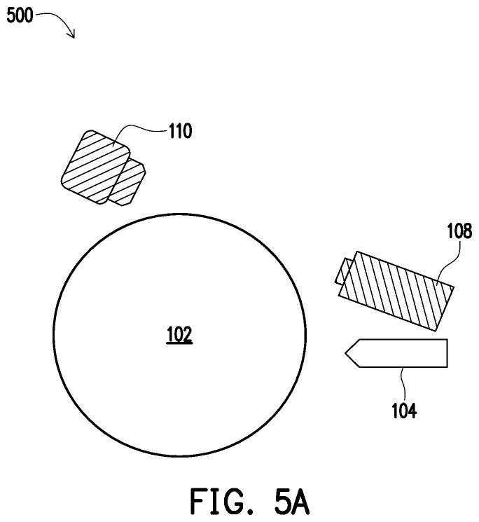

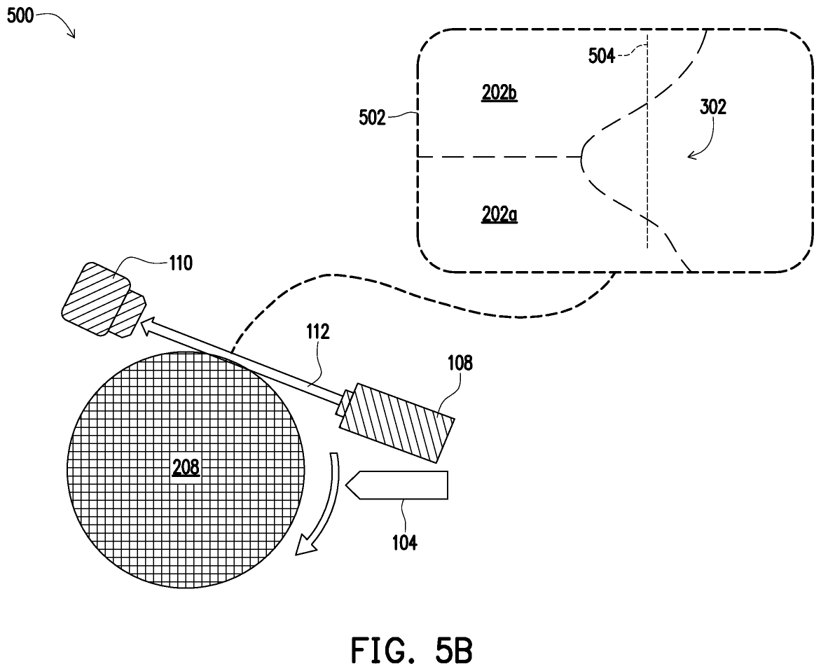

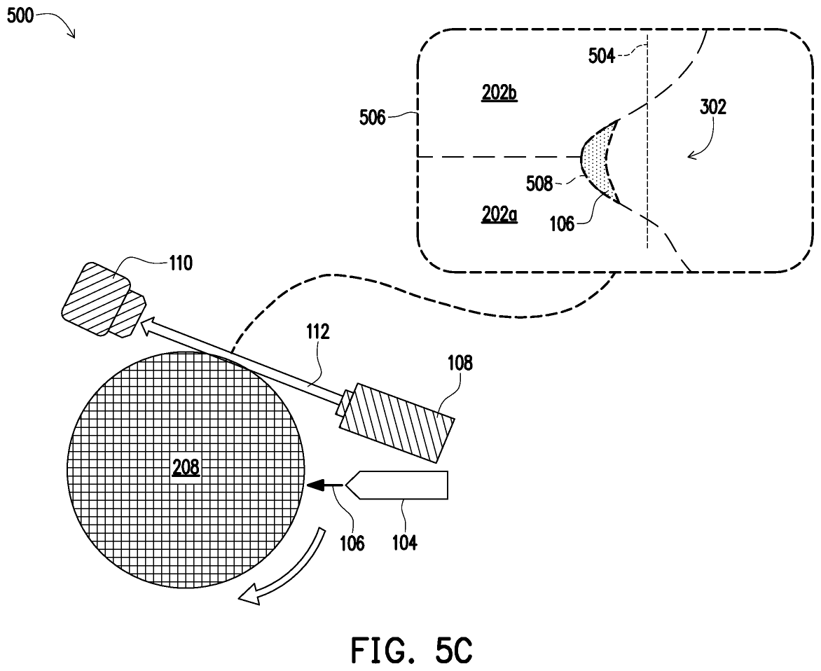

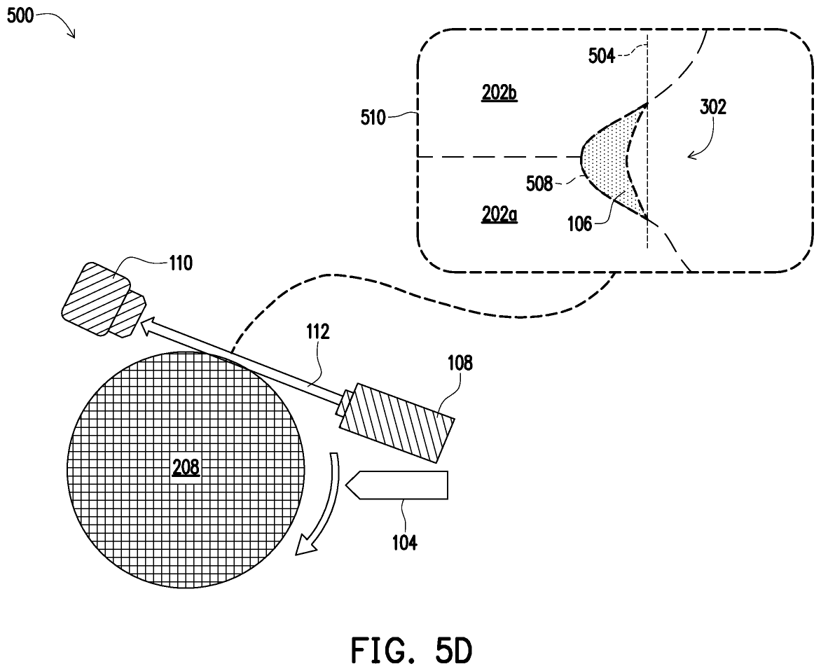

FIGS. 5A-5D are diagrams of an example scaling operation 500 using the semiconductor sealant tool 100 described herein. The sealing operation 500 may be performed to dispense a sealant (e.g., the sealant 116) into a beveled region (e.g., the beveled region 302) between a pair of semiconductor substrates (e.g., the semiconductor substrate 202a and the semiconductor substrate 202b). The sealing operation 500 may use one or more features or aspects of systems and/or components described in connection with FIGS. 1-4 and elsewhere herein.

FIG. 5A shows components of the semiconductor sealant tool 100, including the platen 102, the jet nozzle 104, the light source 108, and the optical sensor 110.

FIG. 5B shows the stack of semiconductor substrates 208 that have been received onto the platen 102. The stack of semiconductor substrates 208 may include two or more semiconductor substrates, including the semiconductor substrate 202a and the semiconductor substrate 202b, that are bonded together using one or more bonding operations described in connection with FIG. 2 (e.g., a “WOW” bonding process).

As part of the sealing operation 500 and as shown in FIG. 5B, the platen 102 may hold the stack of semiconductor substrates 208 and rotate the stack of semiconductor substrates 208 about an axis. In some implementations, a velocity, a direction, and/or an acceleration related to rotation of the platen 102 (and/or the stack of semiconductor substrates 208) is determined and/or adjusted by a controller (e.g., the controller 402 or another computing device) communicating with a motor system linked to the platen 102.

Further, as part of the operation series of operations and as shown in FIG. 5B, the light source 108 may project the electromagnetic waves 112 towards the beveled region 302. The electromagnetic waves 112 may correspond to light waves such as white light waves, red light waves, green light waves, or another color of waves. The optical sensor 110 may receive portions of the electromagnetic waves that are reflected from the beveled region 302.

In FIG. 5B, the controller (or another computing device) receives optical feedback (e.g., first optical feedback) from the optical sensor 110. Using interferometry techniques, laser triangulation techniques, or other suitable optical analysis techniques, the controller may determine a status 502 of the beveled region 302. As an example, determining the status 502 of the beveled region 302 (the status of the beveled region 302 upon receipt of the stack of semiconductor substrates 208) may include determining an edge profile of the beveled region 302 (e.g., contours of the semiconductor substrate 202a and the semiconductor substrate 202b). Additionally, or alternatively, determining the status 502 of the beveled region 302 may further include determining that there is a negligible amount of a sealant (e.g., the sealant 116) within the beveled region 302.

Using the edge profile and/or the determination of the negligible amount of the sealant, the controller may compute an amount of the sealant needed to fill the beveled region 302 to satisfy a threshold 504. In some implementations, the threshold 504 corresponds to fill radius of the sealant. The fill radius of the sealant, which may correspond to a distance from a center of the stack of semiconductor substrates 208, may be included in a range of approximately 149.7 millimeters to approximately 149.9 millimeters. If the fill radius of the sealant is less than approximately 149.7 millimeters, a risk of delamination and/or peeling at a bond interface (e.g., the bond interface 304) may increase during a subsequent thinning or grinding operation. If the fill radius of the sealant is greater than 149.8 millimeters, a risk of bleeding of the sealant to cause contamination defects may increase. However, other values and ranges for the fill radius of the sealant are within the scope of the present disclosure.

Turning to FIG. 5C, and as part of the sealing operation 500, the platen 102 rotates the stack of semiconductor substrates 208 at a rotational velocity as the jet nozzle 104 dispenses the sealant 116 into the beveled region 302. Further, the optical sensor 110 provides optical feedback (e.g., second optical feedback) to the controller. In some implementations, the optical feedback is related to an accumulation of the sealant 116 within the beveled region 302.

Using the optical feedback, the controller may determine a status 506 of the beveled region 302. Determining the status 506 may include, for an example, determining an amount of the sealant 116 within the beveled region 302. Additionally, or alternatively, determining the status 506 may include determining a profile 508 of the sealant 116 within the beveled region 302. The controller may use the amount and/or the profile 508 in combination with the machine model described in connection with FIG. 4 to make determinations and/or adjustments to the sealing operation 500 (e.g., adjustments to one or more settings related to a dispense rate of the sealant 116, a rotational velocity of the stack of semiconductor substrates 208, or an aim point of the jet nozzle 104).

As shown in FIG. 5D, and based on optical feedback from the optical sensor 110 (e.g., third optical feedback), the controller may determine a status 510 of the beveled region 302. Determining the status 510 may include determining that the amount of the sealant 116 within the beveled region 302 and/or the profile 508 of the sealant 116 within the beveled region 302 satisfies the threshold 504.

Although FIGS. 5A-5D shows example operations of the sealing operation 500, in some implementations, the sealing operation 500 includes additional operations, fewer operations, different operations, or differently arranged operations than those depicted in FIGS. 5A-5D.

FIG. 6 is a diagram of a semiconductor substrate grinding tool 600 described herein. The semiconductor substrate grinding tool 600 includes a semiconductor processing tool that is configured to remove material from a semiconductor substrate using a combination of mechanical grinding and chemical etching (e.g., wet etching).

The semiconductor substrate grinding tool 600 includes a processing chamber 602 in which semiconductor substrates may be processed. In some implementations, the processing chamber 602 may be sealed and/or climate controlled to enable precise control over one or more environmental parameters in the processing chamber. Examples of environmental parameters that may be controlled in the processing chamber 602 include temperature, humidity, oxygen concentration, and/or pressure, among other examples.

A platen 604 may be included in the processing chamber 602. The platen 604 may be configured to receive and support the stack of semiconductor substrates 208 on the platen 604. The size and/or shape of the platen 604 may approximately conform to the stack of semiconductor substrates 208. For example, the platen 604 may be approximately round and may be sized to receive and support a round stack of semiconductor substrates 208.

In some implementations, the platen 604 may be configured to secure the stack of semiconductor substrates 208 against the platen 604 to enable the platen 604 to rotate the stack of semiconductor substrates 208. The stack of semiconductor substrates 208 may include a surface 606 that faces away from the platen 604.

The platen 604 may be coupled with a drive shaft 608, which may drive the rotation of the platen 604. In some implementations, the platen 604 includes a chuck that is configured to secure the stack of semiconductor substrates 208 to the platen 604. The chuck may include a vacuum chuck (e.g., a chuck that uses a vacuum force to bias the stack of semiconductor substrates 208 against the platen 604), an electrostatic chuck (e.g., a chuck that uses an electrostatic force to bias the stack of semiconductor substrates 208 against the platen 604), and/or another type of chuck. In some implementations, a wafer transport tool such as a robot arm may position the stack of semiconductor substrates 208 on the platen 604.

A grinding assembly 610 may be at least partially included in the processing chamber 602 of the semiconductor substrate grinding tool 600. The grinding assembly 610 may be configured to mechanically grind the surface 606 of the stack of semiconductor substrates 208 to mechanically remove material from the stack of semiconductor substrates 208. The grinding assembly 610 may include a grinding device 612 that includes an abrasive 614 configured to grind the surface 606 of the stack of semiconductor substrates 208. The grinding device 612 may include a grinding disc, a grinding wheel, a grinding head, and/or another type of grinding device. The abrasive 614 may include one or more grinding elements, such as a sheet of a diamond abrasive, a plurality of diamond abrasive pads, and/or another type of abrasive. In some implementations, the abrasive 614 includes two or more diamond abrasive pads that have different grits (e.g., different roughness or coarseness) of diamond abrasive.

The grinding device 612 may be pivoted via an arm 616. The arm 616 may be controlled through a shaft 618. The arm 616 and/or the shaft 618 of the grinding assembly 610 may be configured to rotate the grinding device 612. The grinding device 612 may be configured to rotate about an axis of the grinding device 612 (e.g., an axis that is approximately perpendicular to the surface 606 of the stack of semiconductor substrates 208) in a grinding operation.

To remove material from the stack of semiconductor substrates 208, the shaft 618 may lower the grinding device 612 onto the surface 606 of the stack of semiconductor substrates 208 such that the abrasive 614 is in physical contact with the surface 606 of the stack of semiconductor substrates 208. In some implementations, the shaft 618 is configured to press the abrasive 614 of the grinding device 612 against the surface 606 of the stack of semiconductor substrates 208 to apply a downforce against the surface 606 of the stack of semiconductor substrates 208. The magnitude of the downforce, along with the rotational velocity of the grinding device 612 and/or the rotational velocity of the platen 604 may be selected to precisely control a material removal rate for removing material from the stack of semiconductor substrates 208. The downforce of the grinding device 612, the rotational velocity of the grinding device 612, and/or the rotational velocity of the platen 604 may be selected based on a thickness of the stack of semiconductor substrates 208, based on a grit of the abrasive 614, based on an amount of material to be removed from the stack of semiconductor substrates 208, based on a material of the stack of semiconductor substrates 208, and/or based on another parameter.

In some implementations, the sealant 116 (e.g., the sealant 116 within the beveled regions 302 of the stack of semiconductor substrates 208) absorbs vibrations and/or mechanical stresses induced to the stack of semiconductor substrates 208 during an operation performed by the semiconductor grinding tool 600 (e.g., an operation such as the thinning operation 210 described in connection with FIG. 2). As a result of the sealant 116 absorbing the vibrations and/or mechanical stresses, a likelihood of defects within the stack of semiconductor substrates 208 (e.g., cracks within the semiconductor substrate 202a and the semiconductor substrate 202b, chipping or pitting within surfaces of integrated circuit dies near perimeters of the semiconductor substrate 202a and the semiconductor substrate 202b, or delamination at the bond interface 304 between the semiconductor substrate 202a and the semiconductor substrate 202b) may be reduced.

Through use of in-line monitoring techniques described in connection with FIGS. 1-5D and elsewhere herein, a consistency of amounts and/or profiles of the sealant 116 within beveled regions (e.g., the beveled region(s) 302) across a population of stacks of semiconductor substrate(s) 208 may be improved. Through this improvement, a yield of the population of stacks of semiconductor substrate(s) 208 (e.g., due to the reduction in the likelihood of defects induced by the semiconductor grinding tool 600) may increase relative to another population of stacks of semiconductor substrates where detecting amounts and/or profiles of the sealant 116 within the beveled regions rely on off-line monitoring techniques that use SEM data and/or AFM data. In this way, an amount of resources (e.g., semiconductor manufacturing tools, raw materials, labor, and/or computing resources) needed to manufacture the population of the stacks of semiconductor substrate(s) is reduced.

As indicated above, FIG. 6 is provided as an example. Other examples may differ from what is described with regard to FIG. 6.

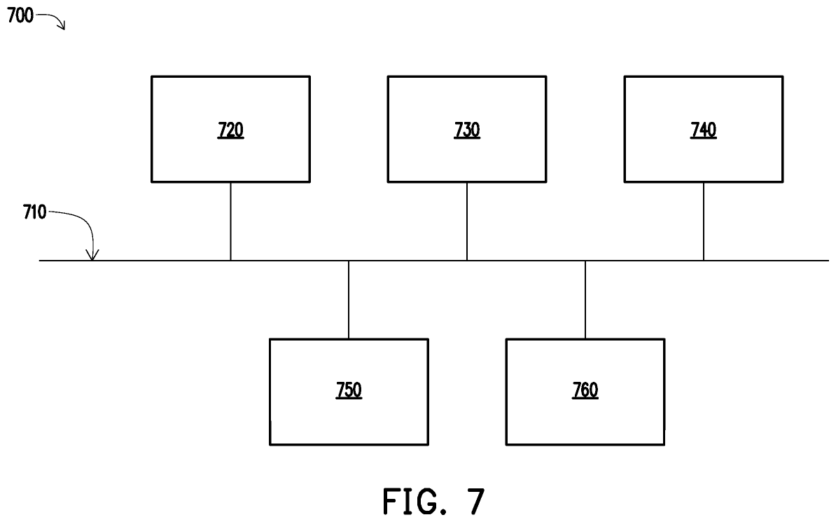

FIG. 7 is a diagram of example components of one or more devices 700 of FIGS. 1, 4, and 6 described herein. The device 700 may correspond to the semiconductor sealant tool 100, a motor component of the platen 102, a pump component of the jet nozzle 104, the light source 108, the optical sensor 110, and/or the controller 402. In some implementations, the semiconductor sealant tool 100, a motor component of the platen 102, a pump component of the jet nozzle 104, the light source 108, the optical sensor 110, and/or the controller 402 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

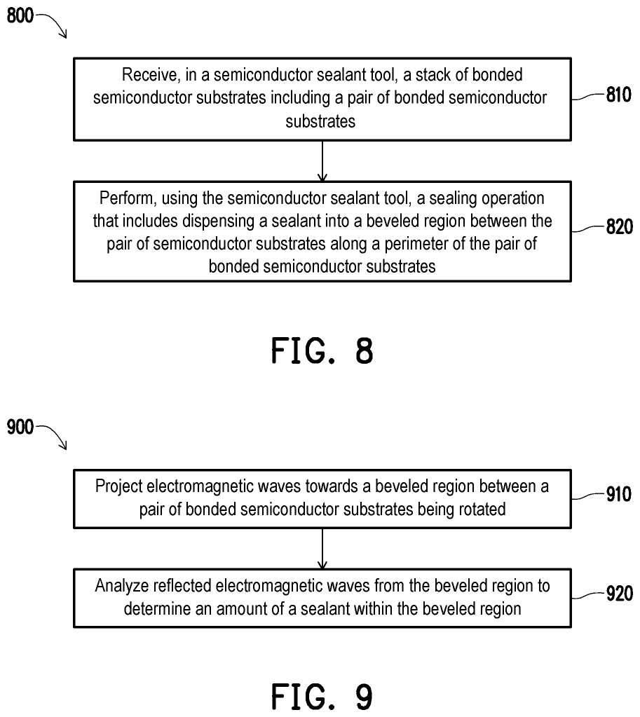

FIG. 8 is a flowchart of an example process 800 associated with an in-line wafer edge sealing monitor descried herein. In some implementations, one or more process blocks of FIG. 8 are performed by one or more semiconductor processing tools (e.g., the semiconductor sealant tool 100, a motor component of the platen 102, a pump component of the jet nozzle 104, the light source 108, the optical sensor 110, and/or the controller 402). Additionally, or alternatively, one or more process blocks of FIG. 8 may be performed by one or more components of device 700, such as processor 720, memory 730, input component 740, output component 750, and/or communication component 760.

As shown in FIG. 8, process 800 may include receiving, in a semiconductor sealant tool, a stack of bonded semiconductor substrates including a pair of bonded semiconductor substrates (block 810). For example, the process 800 may include receiving, in a semiconductor sealant tool (e.g., the semiconductor sealant tool 100), a stack of bonded semiconductor substrates (e.g., the stack of semiconductor substrates 208) including a pair of bonded semiconductor substrates (e.g., the semiconductor substrate 202a and the semiconductor substrate 202b), as described herein.

As further shown in FIG. 8, process 800 may include performing, using the semiconductor sealant tool, a sealing operation that includes dispensing a sealant into a beveled region between the pair of semiconductor substrates along a perimeter of the pair of bonded semiconductor substrates (block 820). For example, the process 800 may include performing, using the semiconductor sealant tool, a sealing operation (e.g., the sealing operation 500) that includes dispensing a sealant (e.g., the sealant 116) into a beveled region (e.g., the beveled region 302) between the pair of semiconductor substrates along a perimeter of the pair of bonded semiconductor substrates, as described herein. In some implementations, optical feedback that is related to an accumulation of the sealant within the beveled region is obtained during the sealing operation. In some implementations, a dispense rate of the sealant is adjusted during the scaling operation based on whether the accumulation of the sealant within the beveled region satisfies a threshold (e.g., the threshold 504).

Process 800 may include additional implementations, such as any single implementation or any combination of implementations described below and/or in connection with one or more other processes described elsewhere herein.

In a first implementation, the optical feedback includes first optical feedback related to an edge profile of the beveled region, and second optical feedback related to a fill radius of the sealant within the beveled region.

In a second implementation, the optical feedback corresponds to white light interferometry feedback.

In a third implementation, alone or in combination with one or more of the first and second implementations, the optical feedback corresponds to three-dimensional laser triangulation feedback.

In a fourth implementation, alone or in combination with one or more of the first through third implementations, dispensing the sealant includes dispensing a dimethyldiethoxysilane compound, a tetraethyl orthosilicate compound, a polydimethylsiloxane compound, or a polysilazanes compound.

In a fifth implementation, alone or in combination with one or more of the first through fourth implementations, process 800 includes rotating, using the semiconductor sealant tool, the stack of bonded semiconductor substrates about a first axis during the sealing operation, wherein the first axis is approximately orthogonal to a second axis along which the sealant is dispensed into the beveled region by a jet nozzle (e.g., the jet nozzle 104) of the semiconductor sealant tool.

In a sixth implementation, alone or in combination with one or more of the first through fifth implementations, performing the sealing operation further includes adjusting a rate of the rotating of the stack of bonded semiconductor substrates based on the optical feedback.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

FIG. 9 is a flowchart of an example process 900 associated with an in-line wafer edge sealing monitor descried herein. In some implementations, one or more process blocks of FIG. 9 are performed by one or more semiconductor processing tools (e.g., the semiconductor sealant tool 100, a motor component of the platen 102, a pump component of the jet nozzle 104, the light source 108, the optical sensor 110, and/or the controller 402). Additionally, or alternatively, one or more process blocks of FIG. 9 may be performed by one or more components of device 700, such as processor 720, memory 730, input component 740, output component 750, and/or communication component 760.

As shown in FIG. 9, process 900 may include projecting electromagnetic waves towards a beveled region between a pair of bonded semiconductor substrates being rotated (block 910). For example, and as part of process 900, the light source 108 may project electromagnetic waves (e.g., the electromagnetic waves 112) towards a beveled region (e.g., the beveled region 302) between a pair of bonded semiconductor substrates (e.g., the semiconductor substrate 202a and the semiconductor substrate 202b) being rotated, as described herein.

As further shown in FIG. 9, process 900 may include analyzing reflected electromagnetic waves from the beveled region to determine an amount of a sealant within the beveled region (block 920). For example, the controller 402 may analyze reflected electromagnetic waves from the beveled region to determine an amount of a sealant (e.g., the sealant 116) within the beveled region, as described herein.

Process 900 may include additional implementations, such as any single implementation or any combination of implementations described below and/or in connection with one or more other processes described elsewhere herein.

In a first implementation, process 900 includes analyzing the reflected electromagnetic waves from the beveled region to determine a shape or a profile (e.g., the profile 508) of the sealant within the beveled region.

In a second implementation, alone or in combination with the first implementation, projecting the electromagnetic waves towards the beveled region includes splitting white light into a first set of light waves along a target path that leads to the beveled region between a pair of bonded semiconductor substrates (e.g., the semiconductor substrate 202a and the semiconductor substrate 202b) being rotated and into a second set of light waves along an adjacent reference path, and wherein analyzing the reflected electromagnetic waves to determine the amount of the sealant within the beveled region includes recombining portions of the first set of light waves that are reflected from the beveled region with the second set of light waves to determine an interference pattern, and analyzing the interference pattern to determine the amount of the sealant within the beveled region between the pair of bonded semiconductor substrates.

In a third implementation, alone or in combination with one or more of the first and second implementations, projecting the electromagnetic waves towards the beveled region includes projecting a laser light towards the beveled region, and wherein analyzing the reflected electromagnetic waves from the beveled region to determine the amount of the sealant within the beveled region includes analyzing positions of one or more portions of the laser light that are reflected from the beveled region to determine the amount of the sealant within the beveled region between the pair of bonded semiconductor substrates.

In a fourth implementation, alone or in combination with one or more of the first through third implementations, process 900 includes adjusting a dispense rate of the sealant based on a machine learning model.

In a fifth implementation, alone or in combination with one or more of the first through fourth implementations, process 900 includes adjusting a rotational velocity of the pair of bonded semiconductor substrates being rotated based on a machine learning model.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

Some implementations herein provide for a system and methods for in-line monitoring of a sealant being dispensed by a jet nozzle in a beveled region along a perimeter of a stack of semiconductor substrates. The system includes an automated optical inspection system. During the dispensing of the sealant by the jet nozzle, the automated optical inspection system may monitor an amount of an accumulation of the sealant within the beveled region.

Through in-line monitoring, a consistency of amounts of the sealant and/or a profile of the sealant as dispensed across a population of stacks of semiconductor substrates may be improved. Through this improvement, a population of stacks of semiconductor substrates having filled beveled regions that satisfy sealant amount and/or profile thresholds may increase relative to another population of stacks of semiconductor substrates having filled beveled regions that rely on off-line monitoring using SEM data and/or AFM data techniques.

In this way, a yield of the population of stacks of semiconductor substrates is improved. By improving the yield, an amount of resources (e.g., semiconductor manufacturing tools, raw materials, labor, and/or computing resources) needed to manufacture the population of the stacks of semiconductor substrates is reduced.

As described in greater detail above, some implementations described herein provide a method. The method includes receiving, in a semiconductor sealant tool, a stack of bonded semiconductor substrates including a pair of bonded semiconductor substrates. The method includes performing, using the semiconductor sealant tool, a sealing operation that includes dispensing a sealant into a beveled region between the pair of semiconductor substrates along a perimeter of the pair of bonded semiconductor substrates, where optical feedback that is related to an accumulation of the sealant within the beveled region is obtained during the sealing operation, and where a dispense rate of the sealant is adjusted during the sealing operation based on whether the accumulation of the sealant within the beveled region satisfies a threshold.

As described in greater detail above, some implementations described herein provide a method. The method includes projecting electromagnetic waves towards a beveled region between a pair of bonded semiconductor substrates being rotated. The method includes analyzing reflected electromagnetic waves from the beveled region to determine an amount of a sealant within the beveled region.

As described in greater detail above, some implementations described herein provide a system. The system includes a platen. The system includes a sealant dispensing system. The system includes an automated optical inspection system. The system includes a control system configured to contemporaneously, rotate the platen compute an amount of a sealant in a beveled region adjacent to a bond region between two semiconductor substrates held by the platen based on optical feedback generated by the automated optical inspection system adjust a dispense rate of the sealant into the beveled region by the sealant dispensing system based on a comparison of the amount to a threshold.

As used herein, “contemporaneously” may, depending on the context, refer to an occurrence “at the same time” or “within a threshold at the same time”.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving, in a semiconductor sealant tool, a stack of bonded semiconductor substrates including a pair of bonded semiconductor substrates; and
performing, using the semiconductor sealant tool, a sealing operation that includes dispensing a sealant into a beveled region between the pair of semiconductor substrates along a perimeter of the pair of bonded semiconductor substrates,
wherein optical feedback that is related to an accumulation of the sealant within the beveled region is obtained during the sealing operation, and
wherein a dispense rate of the sealant is adjusted during the sealing operation based on whether the accumulation of the sealant within the beveled region satisfies a threshold.

2. The method of claim 1, wherein the optical feedback comprises:
first optical feedback related to an edge profile of the beveled region; and
second optical feedback related to a fill radius of the sealant within the beveled region.

3. The method of claim 1, wherein the optical feedback corresponds to white light interferometry feedback.

4. The method of claim 1, wherein the optical feedback corresponds to three-dimensional laser triangulation feedback.

5. The method of claim 1, wherein dispensing the sealant comprises dispensing:
a dimethyldiethoxysilane compound,
a tetraethyl orthosilicate compound,
a polydimethylsiloxane compound, or
a polysilazanes compound.

6. The method of claim 1, further comprising:
rotating, using the semiconductor sealant tool, the stack of bonded semiconductor substrates about a first axis during the sealing operation,
wherein the first axis is approximately orthogonal to a second axis along which the sealant is dispensed into the beveled region by a jet nozzle of the semiconductor sealant tool.

7. The method of claim 6, wherein performing the sealing operation further comprises:
adjusting a rate of the rotating of the stack of bonded semiconductor substrates based on the optical feedback.

8. A method, comprising:
projecting electromagnetic waves towards a beveled region between a pair of bonded semiconductor substrates being rotated; and
analyzing reflected electromagnetic waves from the beveled region to determine an amount of a sealant within the beveled region.

9. The method of claim 8, further comprising:
analyzing the reflected electromagnetic waves from the beveled region to determine a shape or a profile of the sealant within the beveled region.

10. The method of claim 8, wherein projecting the electromagnetic waves towards the beveled region comprises:
splitting white light into a first set of light waves along a target path that leads to the beveled region between a pair of bonded semiconductor substrates being rotated and into a second set of light waves along an adjacent reference path, and
wherein analyzing the reflected electromagnetic waves to determine the amount of the sealant within the beveled region comprises:
recombining portions of the first set of light waves that are reflected from the beveled region with the second set of light waves to determine an interference pattern; and
analyzing the interference pattern to determine the amount of the sealant within the beveled region between the pair of bonded semiconductor substrates.

11. The method of claim 8, wherein projecting the electromagnetic waves towards the beveled region comprises projecting a laser light towards the beveled region, and
wherein analyzing the reflected electromagnetic waves from the beveled region to determine the amount of the sealant within the beveled region comprises:
analyzing positions of one or more portions of the laser light that are reflected from the beveled region to determine the amount of the sealant within the beveled region between the pair of bonded semiconductor substrates.

12. The method of claim 8, further comprising:
adjusting a dispense rate of the sealant based on a machine learning model.

13. The method of claim 8, further comprising:
adjusting a rotational velocity of the pair of bonded semiconductor substrates being rotated based on a machine learning model.

14. A system, comprising:
a platen;
a sealant dispensing system;
an automated optical inspection system; and
a control system configured to contemporaneously:
rotate the platen;
compute an amount of a sealant in a beveled region adjacent to a bond region between two semiconductor substrates held by the platen based on optical feedback generated by the automated optical inspection system; and
adjust a dispense rate of the sealant into the beveled region by the sealant dispensing system based on a comparison of the amount to a threshold.

15. The system of claim 14, wherein the automated optical inspection system comprises:
a white light interferometry system.

16. The system of claim 14, wherein the automated optical inspection system comprises:
a three-dimensional laser triangulation system.

17. The system of claim 14, wherein the sealant dispensing system comprises a jet nozzle configured to dispense a compound comprising:
filler particulates.

18. The system of claim 14, wherein the control system is further configured to contemporaneously:
determine a profile or a shape of the sealant in the beveled region based on the optical feedback generated by the automated optical inspection system.

19. The system of claim 18, wherein the control system is further configured to contemporaneously:
adjust an aim point of a jet nozzle of the sealant dispensing system based on the profile or the shape.

20. The system of claim 18, wherein the control system is further configured to contemporaneously:
adjust a rotational velocity of the platen based on the profile or the shape.
